(19) United States
(12) Patent Application Publication
(10) Pub. No.: US 2015/0058550 A1
(43) Pub. Date: Feb. 26, 2015

(54) INFORMATION RECORDING APPARATUS THAT PERFORMS REFRESH OF MEMORY AND CONTROL METHOD THEREFOR

(71) Applicant: CANON KABUSHIKI KISHA, Tokyo (JP)

(72) Inventor: Fumio MIKAMI, Chigasaki-shi (JP)

(21) Appl. No.: 14/457,337

(22) Filed: Aug. 12, 2014

(30) Foreign Application Priority Data
Aug. 22, 2013 (JP) 2013-172253

(51) Int. Cl. G11C 16/34

(52) U.S. Cl. CPC G11C 16/3431
USPC 711/106

(57) ABSTRACT

An information recording apparatus which is capable of preventing data loss due to a decrease in a time period for which data is retained in a memory, and performing refresh of the memory mounted on a main body of the information recording apparatus. When the number of times of data erasure in the memory is updated, a table showing data retention time periods corresponding to the number of times of data erasure in the memory is referred to, and a date and time at which refresh of the memory should be performed within a data retention time period corresponding to the number of times of data erasure is set. Whether it is possible to perform refresh of the memory at the set date and time is judged, and when it is possible to perform refresh of the memory at the set date and time, refresh of the memory is performed.

### BACKGROUND OF THE INVENTION

1. Field of the Invention

The present invention relates to an information recording apparatus and a control method therefor, and in particular to an information recording apparatus capable of preventing data in an SSD (solid state drive) from being lost due to aging variation.

2. Description of the Related Art

Conventionally, MFPs (multifunction peripherals) with hard disks have been commercialized, but troubles unique to hard disks such as crush have not been solved yet. For this reason, substitution of SSDs for hard disks has come under review. For example, Japanese Laid-Open Patent Publication (Kokai) No. 2007-48347 discloses a technique of, in order to prevent loss of data due to aging variation, automatically refreshing a semiconductor memory, which is a semiconductor memory card and separate from a main body, using a built-in battery according to data writing/erasure histories of the semiconductor memory.

However, a NAND FLASH memory device which is used for an SSD has a property of losing data when a predetermined time period has elapsed after the data was written. Further, the NAND FLASH memory device also has a property that a time period for which data is retained decreases as the number of times of data writing increases. When data on the SSD is lost in the MFP, a trouble occurs, e.g., a system does not start, or user data is lost. It should be noted that because the NAND FLASH memory device cannot be directly overwritten because of its structure, and data is written into the NAND flash memory device after original data is erased, the number of times of data writing corresponds to the number of times of data erasure.

In Japanese Laid-Open Patent Publication (Kokai) No. 2007-48347, there is proposed an arrangement in which a semiconductor memory is automatically refreshed using a timer and a battery power supply while the semiconductor memory is separate from the main body, but no consideration is given to refresh of the semiconductor memory being mounted on the main body. Moreover, there is proposed an arrangement in which the semiconductor memory is automatically refreshed using the number of times of data erasure in each block of the semiconductor memory, but no consideration is given to refresh of the semiconductor memory being mounted on the main body, and hence no consideration is given to how the main body which is a control apparatus recognizes data erasure histories of the semiconductor memory, that is, how the number of times of data erasure is counted.

### SUMMARY OF THE INVENTION

The present invention provides an information recording apparatus which is capable of preventing data loss due to a decrease in a time period for which data is retained in a memory, and properly performing refresh of the memory which is mounted on a main body of the information recording apparatus, and a control method therefor.

Accordingly, a first aspect of the present invention provides an information recording apparatus comprising a memory, a refresh unit configured to perform refresh of the memory, a table configured to show data retention time periods corresponding to the number of times of data erasure in the memory, a setting unit configured to refer to the table and set, based on the number of times of data erasure in the memory, a date and/or time at which refresh of the memory should be performed within a data retention time period corresponding to the number of times of data erasure, and a control unit configured to, based on the set date and/or time at which refresh of said memory should be performed, cause said refresh unit to perform refresh of said memory.

A second aspect of the present invention provides an information recording apparatus comprising a memory, a refresh unit configured to perform refresh of the memory, a battery, and a power selection unit configured to select one of a first power supply and the battery as a power supply that supplies power to the refresh unit, wherein the power selection unit is configured to select the first power supply in order to refresh the memory when the power can be supplied from the first power supply, and select the battery in order to refresh the memory when the power cannot be supplied from the first power supply.

A third aspect of the present invention provides a method for controlling refresh of a memory, comprising referring to a table which shows data retention time periods corresponding to the number of times of data erasure in the memory, setting, based on the number of times of data erasure in the memory being updated, a date and/or time at which refresh of the memory should be performed within a data retention time period corresponding to the number of times of data erasure, and performing, based on the set date and/or time at which refresh of the memory should be performed, refresh of the memory.

According to the present invention, loss of data due to a decrease in the time period for which data is retained in the memory, and refresh of the memory mounted on the main body of the MFP can be properly performed.

Further features of the present invention will become apparent from the following description of exemplary embodiments (with reference to the attached drawings).

### BRIEF DESCRIPTION OF THE DRAWINGS

FIG. 1 is a block diagram schematically showing an arrangement of an MFP to which an information recording apparatus according to a first embodiment of the present invention is applied.

FIG. 2 is a flowchart showing the flow of a control process for a CPU to set a date and time at which SSD will be refreshed.

FIG. 3 is a view showing an exemplary data retention time period table.

FIG. 4 is a flowchart showing an SSD refresh performed by the CPU.

FIG. 5 is a block diagram schematically showing an arrangement of an MFP to which an information recording apparatus according to a second embodiment of the present invention is applied.

FIGS. 6A and 6B are timing charts showing operation by a refresh controller on an interrupt signal output from an RTC, a power selector signal D output from a latch circuit, and a latch cancellation signal C output from a refresh controller, in which FIG. 6A shows a case where the MFP is not energized, and FIG. 6B shows a case where the MFP is energized.

### DESCRIPTION OF THE EMBODIMENTS

The present invention will now be described in detail with reference to the drawings showing embodiments thereof.

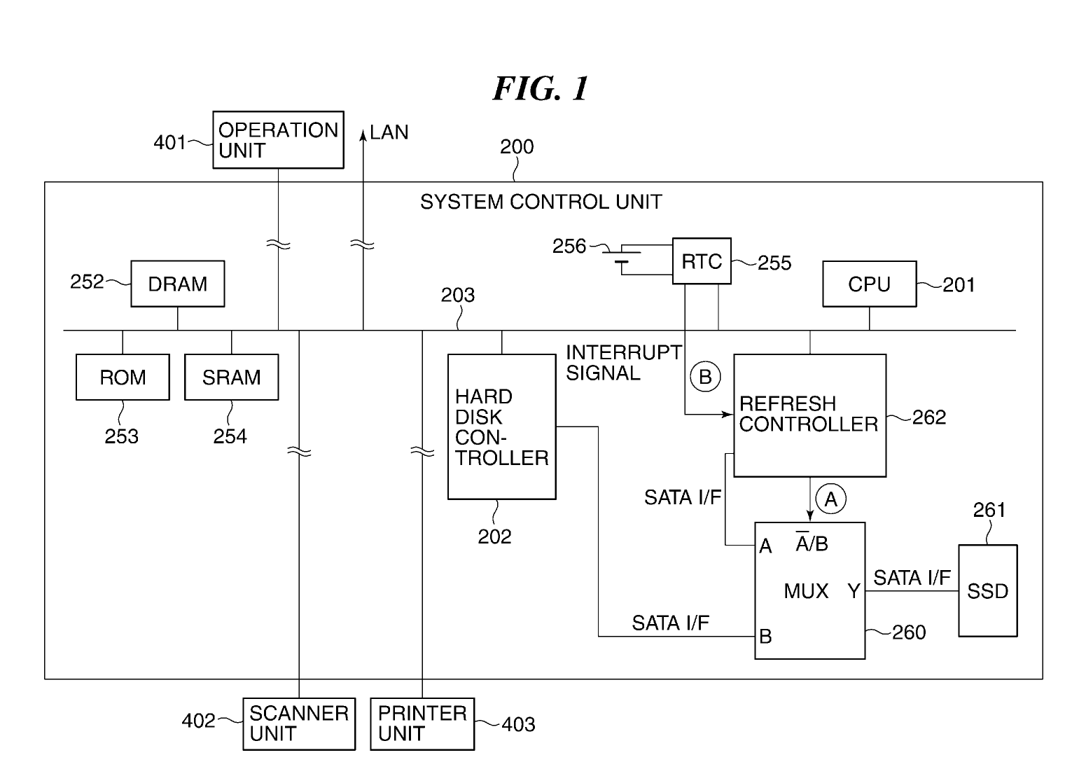

FIG. 1 is a block diagram schematically showing an arrangement of an MFP to which an information recording apparatus according to a first embodiment of the present invention is applied. In the present embodiment, it is assumed that the power to the MFP is on.

Referring to FIG. 1, the MFP is comprised of a system control unit 200, an operation unit 401, a scanner unit 402, and a printer unit 403. The system control unit 200, which has a function of acting as a controller for the MFP, is connected to and controls the operation unit 401, the scanner unit 402, and the printer unit 403.

A CPU 201 centrally controls access to blocks connected to a system bus 203 based on control programs and others stored in a ROM 253. A DRAM 252 is a system work memory for the CPU 201 to operate, and when the power to the MFP is turned off, contents of the DRAM 252 are erased. An SRAM 254 is battery-protected so as to hold stored contents even after the power is turned off. A boot program for the MFP is stored in the ROM 253.

A hard disk controller 202 is a device, which accesses a hard disk (here, an SSD 261) from the CPU 201 via the system bus 203, is connected to a B input terminal of a multiplexer (MUX) 260 via a SATA I/F, and inputs a SATA signal to the B input terminal.

A refresh controller 262 outputs a selection signal to a selection signal A/B terminal of the multiplexer 260 based on an interrupt signal B output from a real-time clock (RTC) 255 which is a timer. The refresh controller 262 inputs a SATA signal to an A input terminal of the multiplexer 260. A Y output terminal of the multiplexer 260 is connected to the SSD 261 via a SATA I/F.

During normal operation, a multiplexer selector signal A which is a selection signal output from the refresh controller 262 is open, and the multiplexer 260 is configured such that a signal input to the B input terminal is output to the Y input terminal. This enables the hard disk controller 202 to access the SSD 261.

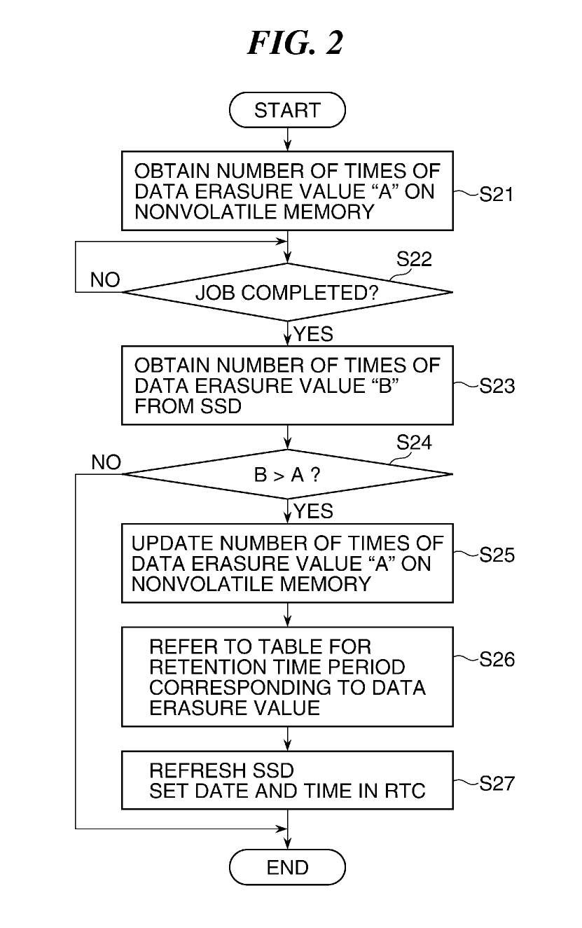

Referring next to FIG. 2, a description will be given of a control flow for setting, in the RTC 255, a date and time at which the SSD 261 will be refreshed.

FIG. 2 is a flowchart showing the flow of a control process for the CPU 201 to set, in the RTC 255, a date and time at which the SSD 261 will be refreshed. This process is realized by the CPU 201 reading out a control program from the ROM 253 and executing the same.

First, in step S21, the CPU 201 reads out a number of times of data erasure value A in the SSD 261 stored in the SRAM 254 which is a nonvolatile memory. The number of times of data erasure value A for the SSD 261 stored in the SARAM 254 can be obtained by the CPU 201 issuing an ATA command via a SATA I/F. Because the number of times of data erasure in the SSD 261 can be obtained by an ATA command, it is unnecessary for the system control unit 200 to have a means for counting the number of times of data erasure in the SSD 261. Thereafter, when a job involving data wiring into the SSD 261 is completed (YES in step S22), the CPU 201 reads out a number of times of data erasure value B from the SSD 261 (step S23).

In step S24, the CPU 201 judges whether or not the number of times of data erasure value was updated before and after the job involving data writing into the SSD 261. Specifically, the number of times of data erasure value A and the number of times of data erasure value B are compared with each other, and when the number of times of data erasure value B>the number of times of data erasure value A, it is considered that the number of times of data erasure in the SSD 261 was updated, followed by the process proceeding to step S25. On the other hand, when the number of times of data erasure value B≦the number of times of data erasure value A, the CPU 201 terminates the process.

In step S25, the CPU 201 updates the number of times of data erasure value A on the SRAM 254 which is a nonvolatile memory.

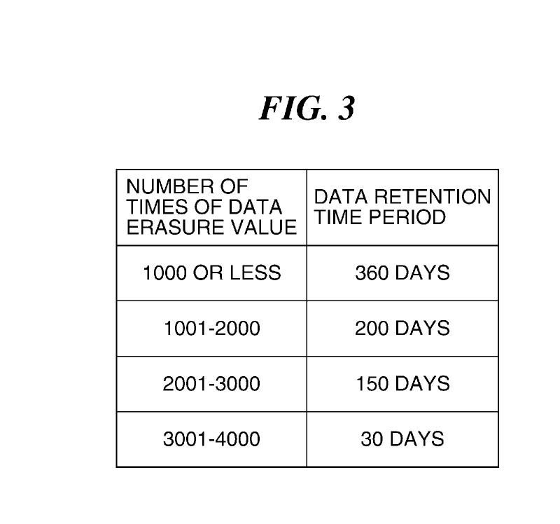

The CPU 201 then refers to a data retention time period table (FIG. 3) being on a program running the MFP (step S26) and sets, in the RTC 255, a data retention time period corresponding to the updated number of times of data erasure value (step S27). For example, when the number of times of data erasure value is 1500, a timer period up to 200 days after the present time is set as a data retention time period in the RTC 255. When the set data retention time period has elapsed, the RTC 255 outputs an interrupt signal B to notify the refresh controller 262 of an interrupt.

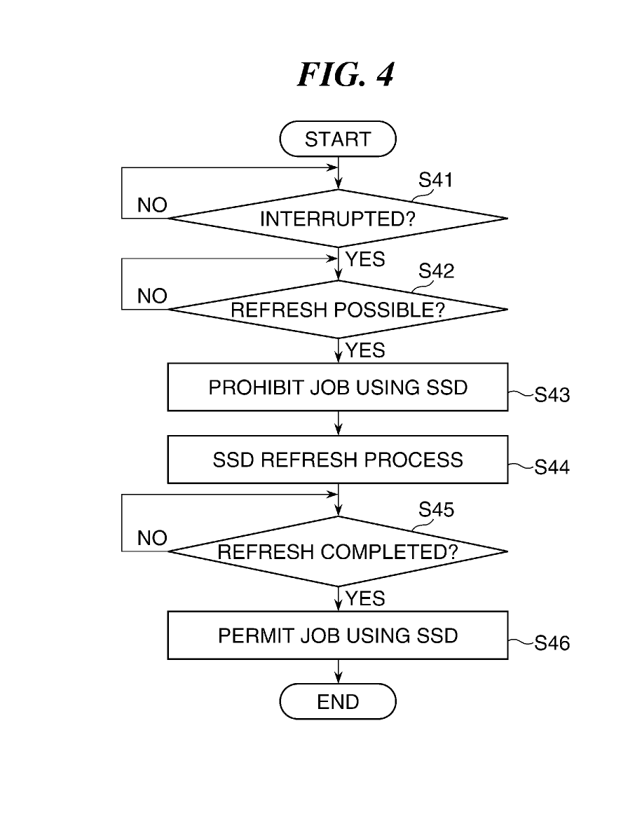

Referring next to FIG. 4, a description will be given of how the SSD 261 is refreshed by the CPU 201.

FIG. 4 is a flowchart showing how the SSD 261 is refreshed by the CPU 201. This process is realized by the CPU 201 reading out a control program from the ROM 253 and executing the same.

The RTC 255, which is a management unit, outputs the interrupt signal B to the refresh controller 262 at a date and time at which the SSD 261 should be refreshed.

Upon receiving the interrupt signal B from the RTC 255 (YES in step S41), the refresh controller 262 inquires of the CPU 201 as to whether it is possible to perform refresh via system bus 203. The CPU 201 having received the inquiry causes the refresh controller 262 to perform refresh when determining that it is possible to perform refresh (YES in step S42). Upon receiving notification about the start of refresh from the refresh controller 262 via the system bus 203, the CPU 201 comes into a state of prohibiting a job which involves access to the SSD 261 (step S43). At this time, the CPU 201 instructs the operation unit 401 to provide an indication to the effect that execution of a job using the SSD 261 is prohibited. Thus, a user can be notified of a condition of the MFP.

Before performing refresh, the refresh controller 262 brings the multiplexer selector signal A to an L (low) level. As a result, the A input terminal and the Y output terminal are connected to each other in the multiplexer 260, and the refresh controller 262 is connected to the SSD 261. Through this connection, the refresh controller 262 performs refresh of memory cells in the SSD 261 by successively reading out all addresses of blocks in the SSD 261 and writing the read-out data to the read-out addresses (step S44). When refresh has been completed for all the addresses in the SSD 261 (YES in step S45), the refresh controller 262 provides notification that the refresh of the SSD 261 has been completed to the CPU 201 via the system bus 203.

Upon receiving the completion notification, the CPU 201 shifts into a state of permitting a job involving access to the SSD 261 (step S46).

As described above, when a job involving data writing into the SSD 261 is completed, and the number of times of data erasure in the SSD 261 is updated, the CPU 201 refers to the data retention time period table showing data retention time periods corresponding to the number of times of data erasure in the SSD 261. A date and time at which refresh of the SSD 261 should be performed within a data retention time period corresponding to the number of times of data erasure is set in the RTC 255. Upon receiving a notification from the RTC 255 at the set date and time at which refresh of the SSD 261 should be performed, the CPU 201 performs refresh of the SSD 261 when judging that it is possible to perform refresh of the SSD 261. As a result, loss of data due to a decrease in the time period for which data is retained in the memory, and refresh of the memory mounted on the main body of the MFP can be properly performed.

In the first embodiment described above, it is assumed that the power to the MFP is on. On the other hand, in a second embodiment, when the power to the MFP is off (the power is shut down), data loss upon lapse of a data retention time period for the SSD 261 is prevented. Not only when the MFP is energized and in use but also when the MFP is not energized, loss of retained data is prevented.

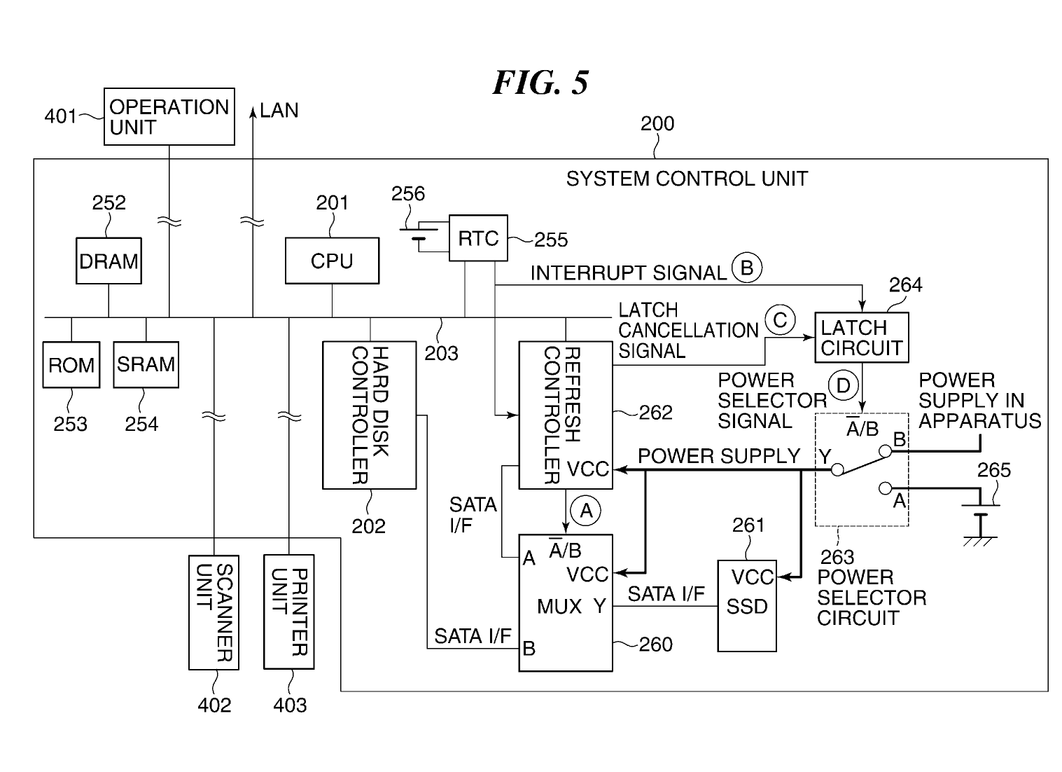

FIG. 5 is a block diagram schematically showing an arrangement of the MFP to which an information recording apparatus according to the second embodiment of the present invention is applied. It should be noted that the same component elements as those in FIG. 1 are designated by the same reference symbols, and description thereof is omitted. Only those differing from the first embodiment will be described below.

Referring to FIG. 5, a power selector circuit 263 selects a power supply in the MFP or a battery 265 as a power supply that supplies power to the refresh controller 262, the multiplexer 260, and the SSD 261. A signal obtained by the latch circuit 264 latching an interrupt signal B output from the RTC 255 is output as a power selector signal D to the power selector circuit 263.

During normal operation, the interrupt signal B is output at a H (high) level from the RTC 255 and latched by the latch circuit 264. An output from the latch circuit 264 is input as the power selector signal D to the power selector circuit 263, and a B input terminal of the power selector circuit 263 is selected, so that the power supply in the MFP is connected to a Y output terminal of the power selector circuit 263, and power is supplied from the power supply in the MFP to the refresh controller 262, the multiplexer 260, and the SSD 261.

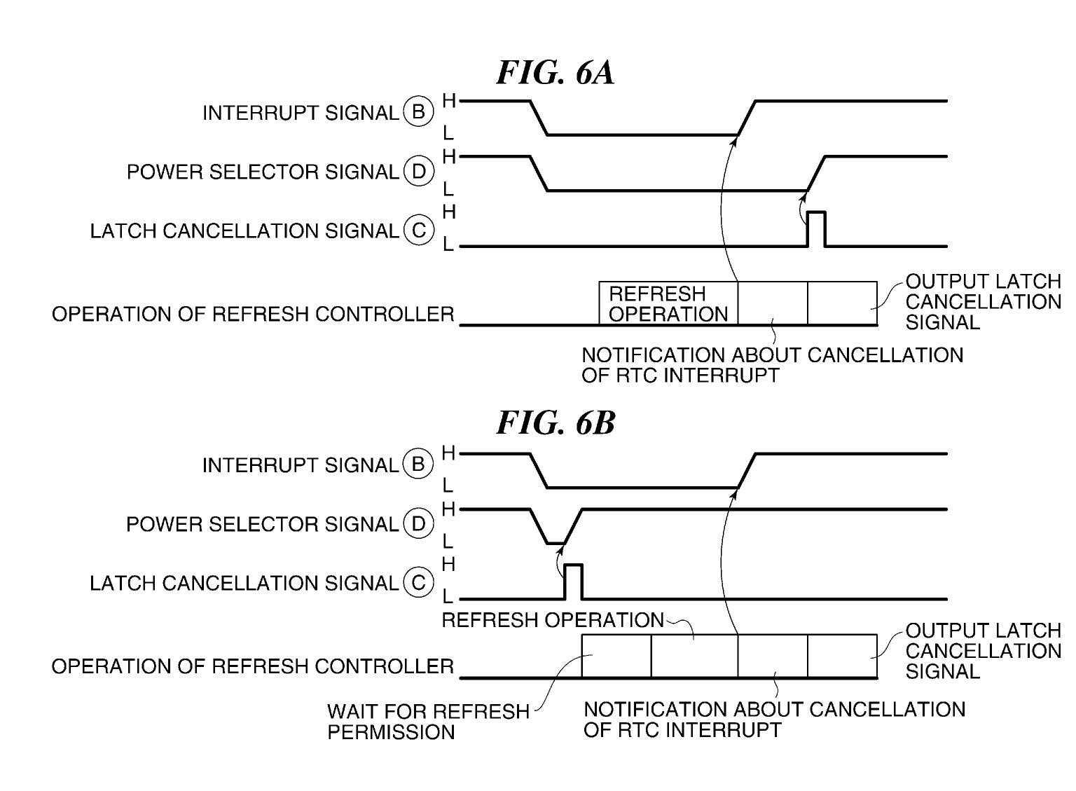

FIGS. 6A and 6B are timing charts showing operation by the refresh controller 262 on an interrupt signal B output from the RTC 255, a power selector signal D output from the latch circuit 264, and a latch cancellation signal D output from the refresh controller 262 relating to refresh of the SSD 261, in which FIG. 6A shows a case where the MFP is not energized, and FIG. 6B shows a case where the MFP is energized.

FIG. 6A shows a case where the MFP is not energized. When the MFP is not energized, the RTC 255 changes the interrupt signal B from the H level to the L level according to a set date and time and outputs the changed interrupt signal B, which in turn is latched by the latch circuit 264. Thus, the L level is obtained as a latch output from the latch circuit 264, and the power selector signal D output to the power selector circuit 263 is at the L level. Accordingly, the A input terminal is selected in the power selector circuit 263, and the battery 265 is connected to the Y output terminal, so that power is supplied from the battery 265 to the refresh controller 262, the multiplexer 260, and the SSD 261.

Thereafter, as with the first embodiment described above, after refreshing the SSD 261, the refresh controller 262 temporarily brings a latch cancellation signal C, which is for resetting the signal latched by the latch circuit 264, from the L level to the H level and then brings the latch cancellation signal C back to the L level again. As a result, the power selector signal D latched by the latch circuit 264 at the L level is reset.

In the above described manner, refresh of the SSD 261 is performed using the battery 265, and when the refresh is completed, the battery 265 is removed.

FIG. 6B shows a case where the MFP is energized. In response to a change in the level of the interrupt signal B from the H level to the L level while the MFP is energized, the refresh controller 262 temporarily brings the latch cancellation signal C from the L level to the H level and brings the latch cancellation signal C to the L level again, thus resetting the latch circuit 264. The latch circuit 264 then selects the power supply in the MFP by bringing the power selector signal D to the H level. After that, the refresh controller 262 requests the CPU 201 to permit refresh, and after refresh is permitted, performs refresh of the SSD 261. During refresh, the SSD 261 cannot be accessed, and hence an indication to the effect that operation modes are limited is provided on the operation unit 401. Thus, the user can be notified of a condition of the MFP.

According to the embodiment described above, the power selector circuit 263 selects the power supply in the MFP or the battery 265 as the power supply that supplies power to the refresh controller 262, the multiplexer 260, and the SSD 261. As a result, when the power to the MFP is not on, data loss due to lapse of the SSD data retention time period can be prevented. Moreover, not only when the MFP is energized and in use, but also when the MFP is not energized, loss of retained data can be prevented.

### OTHER EMBODIMENTS

Embodiments of the present invention can also be realized by a computer of a system or apparatus that reads out and executes computer executable instructions recorded on a storage medium (e.g., non-transitory computer-readable storage medium) to perform the functions of one or more of the above-described embodiment(s) of the present invention, and by a method performed by the computer of the system or apparatus by, for example, reading out and executing the computer executable instructions from the storage medium to perform the functions of one or more of the above-described embodiment(s). The computer may comprise one or more of a central processing unit (CPU), micro processing unit (MPU), or other circuitry, and may include a network of separate computers or separate computer processors. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-172253 filed Aug. 22, 2013, which is hereby incorporated by reference herein in its entirety.

What is claimed is:

1. An information recording apparatus comprising:
a memory;
a refresh unit configured to perform refresh of said memory;
a table configured to show data retention time periods corresponding to the number of times of data erasure in said memory;
a setting unit configured to refer to said table and set, based on the number of times of data erasure in said memory, a date and/or time at which refresh of said memory should be performed within a data retention time period corresponding to the number of times of data erasure; and
a control unit configured to, based on the set date and/or time at which refresh of said memory should be performed, cause said refresh unit to perform refresh of said memory.

2. The information recording apparatus according to claim 1, further comprising:
a management unit configured to manage the date and/or time at which refresh of said memory should be performed,
wherein said control unit is configured to, in response to a notification from said management unit, cause said refresh unit to perform refresh of said memory.

3. The information recording apparatus according to claim 1, wherein said management unit is configured to be operated by a battery.

4. The information recording apparatus according to claim 1, wherein said control unit is further configured to judge whether it is possible to refresh said memory, and upon judging that it is possible to refresh said memory, cause said refresh unit to perform refresh of said memory.

5. The information recording apparatus according to claim 1, wherein upon judging that it is possible to refresh said memory, said control unit prohibits execution of a job using said memory and provides an indication that a job using said memory is prohibited.

6. The information recording apparatus according to claim 1, wherein, when power to the information recording apparatus is off, said refresh unit performs refresh of said memory using another battery different from the battery.

7. The information recording apparatus according to claim 1, wherein said memory is an SSD, and the number of times of data erasure can be read out by an ATA command.

8. The information recording apparatus according to claim 1, wherein, when a job involving data writing into said memory is completed, said control unit obtains the number of times of data erasure from said memory.

9. An information recording apparatus comprising:
a memory;
a refresh unit configured to perform refresh of said memory;
a battery; and
a power selection unit configured to select one of a first power supply and the battery as a power supply that supplies power to the refresh unit,
wherein the power selection unit is configured to select the first power supply in order to refresh said memory when the power can be supplied from the first power supply, and select the battery in order to refresh said memory when the power cannot be supplied from the first power supply.

10. A method for controlling refresh of a memory, comprising:
referring to a table which shows data retention time periods corresponding to the number of times of data erasure in said memory;
setting, based on the number of times of data erasure in said memory being updated, a date and/or time at which refresh of said memory should be performed within a data retention time period corresponding to the number of times of data erasure; and
performing, based on the set date and/or time at which refresh of said memory should be performed, refresh of said memory.
